(19) United States
(12) Patent Application Publication
(10) Pub. No.: US 2006/0099800 A1
(43) Pub. Date: May 11, 2006

(54) Method for fabricating low leakage interconnect layers in integrated circuits

(76) Inventors: Chintamani Palsule, Fort Collins, CO (US); Jay Meyer, Fort Collins, CO (US); John H. Stanback, Fort Collins, CO (US); Jeremy A. Theil, Mountain View, CA (US); Mark D. Crook, Fort Collins, CO (US); Kirk A. Lindahl, Louisville, CO (US)

Correspondence Address: AGILENT TECHNOLOGIES, INC.;INTELLECTUAL PROPERTY ADMINISTRATION, LEGAL DEPT., P.O. BOX 7599, M/S DL429, LOVELAND, CO, 80537-0599, US

(21) Appl. No.: 10/984,701

(22) Filed: Nov. 9, 2004

(51) Int. Cl. H01L 21/4763

(52) U.S. Cl. 438/636

(57) ABSTRACT

A method for fabricating a low leakage integrated circuit structure. An antireflective layer is disposed without intervening layers directly onto the top of an interconnect conductor, and a dielectric layer is disposed over the antireflective layer. The interconnect conductor is aluminum; the antireflective layer is titanium nitride, and the antireflective layer has thickness less than or equal to 650 angstroms and greater than or equal to 150 angstroms. A contact window is opened with the contact window extending at least down to the antireflective layer.

### BACKGROUND

Most advanced integrated circuit (IC) processes having 0.35 micron or smaller geometries include an antireflective (AR) coating on top of each metallization layer to improve the lithography process margin in patterning smaller features in the integrated circuit. Such antireflective coating reduces exposure dispersion of the interconnect layer photoresist, thus providing a sharper image pattern which improves the definition of interconnect features. Typically for aluminum/tungsten (Al/W) based metallization systems, a flash titanium layer (flash Ti) is applied between the aluminum (Al) and the antireflective layer which is generally titanium nitride (TiN). Tungsten is used to fill the vias that interconnect the layers of aluminum. The flash titanium layer is also referred to as a titanium initiation layer. The flash titanium layer is necessary to prevent a broad distribution of contact resistance which would otherwise result from the formation of aluminum nitride (AlN) during the deposition of the top antireflective titanium nitride, as well as during subsequent exposure to nitrogen plasma during resist ash steps.

Without the flash titanium layer, a few regions of aluminum nitride would be created on top of the aluminum due to the introduction of nitrogen gas into the sputtering chamber during the deposition of the top antireflective titanium nitride onto the aluminum. If the aluminum nitride layer regions happen to be at the bottom of a contact, then such contacts would have higher contact resistance resulting in a broad distribution of contact resistance to the next interconnect layer.

The flash layer of titanium and the antireflective coating of titanium nitride are generally deposited using the same sputtering chamber. Titanium is sputtered from a titanium target in the chamber during the first part of the process. Then the antireflective coating of titanium nitride is deposited on the wafers in the same chamber by introducing the nitrogen into the chamber after a set delay following the onset of titanium sputtering.

During subsequent thermal processing, it is anticipated that this titanium will react with the aluminum to form titanium aluminide (TiAl₃) which will prevent hydrogen gettering by this layer of titanium. However, due to the normal practice of depositing the layer of flash titanium in most integrated circuit processes, an unintentional layer of titanium nitride is deposited between the aluminum and the titanium. This extra, unintentional layer of titanium nitride inhibits the reaction of the titanium layer with the aluminum during subsequent thermal processing unless the temperature and temperature duration (the thermal budget) of subsequent processing steps is very high. In most integrated circuit processes, the thermal budget of steps subsequent to aluminum deposition is not sufficient to overcome the barrier presented by the unintentional layer of titanium nitride.

Thus, a result of the failure to overcome the barrier of the unintentional layer of titanium nitride is the gettering of hydrogen by the titanium layer. Hydrogen gettering by the titanium layer results in insufficient passivation of dangling bonds at the silicon/silicon dioxide interface which leads to higher leakage currents in such integrated circuits. Depending upon the specific spatial distribution of the metallization in the integrated circuit, these dangling bonds at the silicon/oxide interface can lead to larger leakage currents with more variability across large area arrays as are commonly found in CMOS Image sensors.

Leakage current for a light sensitive element, for example as found in a pixel of an image sensor, is often referred to as the dark current of the device, i.e., the current through the light sensitive element in the absence of any light. The lowest light intensity that is detectable by the device is dictated by the noise in the device and the dark current. Thus, it is important to maintain the leakage currents as small as possible, as well as to maintain a uniformity in the magnitudes of the leakage currents across the image sensor.

### SUMMARY

In a representative embodiment, a method for fabricating a low leakage integrated circuit structure is disclosed. The method comprises disposing an antireflective layer without intervening layers directly onto the top of an interconnect conductor and disposing a dielectric layer over the antireflective layer. The interconnect conductor is aluminum; the antireflective layer is titanium nitride, and the antireflective layer has thickness less than or equal to 650 angstroms and greater than or equal to 150 angstroms. A contact window is opened with the contact window extending at least down to the antireflective layer.

In another representative embodiment, an integrated circuit structure is disclosed. The integrated circuit structure comprises an interconnect conductor disposed over other integrated circuit structure, an antireflective layer disposed without intervening layers directly onto the top of the interconnect conductor, and a dielectric layer disposed over the antireflective layer. The interconnect conductor comprises aluminum, and the antireflective layer comprises titanium nitride. The antireflective layer has thickness less than or equal to 650 angstroms and greater than or equal to 150 angstroms. The dielectric layer comprises a contact window with the contact window extending at least down to the antireflective layer.

In yet another representative embodiment, a method for fabricating a low leakage integrated circuit structure is disclosed. The method comprises placing the integrated circuit structure in a deposition chamber, disposing a flash titanium layer without intervening layers directly onto the top of the interconnect conductor, and disposing an antireflective layer over the flash titanium layer. The integrated circuit structure has an interconnect conductor disposed thereon. The interconnect conductor comprises aluminum, and the antireflective layer comprises titanium nitride. The above steps are then repeated for at least one additional integrated circuit structure.

Other aspects and advantages of the representative embodiments presented herein will become apparent from the following detailed description, taken in conjunction with the accompanying drawings.

### BRIEF DESCRIPTION OF THE DRAWINGS

The accompanying drawings provide visual representations which will be used to more fully describe various representative embodiments and can be used by those skilled in the art to better understand them and their inherent advantages. In these drawings, like reference numerals identify corresponding elements.

FIG. 1A is a drawing of a cross-section of a part of an integrated circuit structure as described in various representative embodiments.

FIG. 1B is a drawing of a cross-section of another integrated circuit structure as described in various representative embodiments.

FIG. 2 is a drawing of a cross-section of still another integrated circuit structure as described in various representative embodiments.

FIG. 3 is a drawing of a cross-section of yet another integrated circuit structure as described in various representative embodiments.

FIG. 4A is a drawing of a cross-section of an integrated circuit top interconnect layer as described in various representative embodiments.

FIG. 4B is a drawing of a cross-section of an integrated circuit underlying interconnect layer as described in various representative embodiments.

FIG. 4C is a drawing of a cross-section of an integrated circuit structure having the integrated circuit underlying interconnect layer of FIG. 4B.

FIG. 4D is a flow chart of a method for creating an integrated circuit structure having the integrated circuit underlying interconnect layer of FIG. 4B.

FIG. 5A is a drawing of a deposition chamber as described in various representative embodiments.

FIG. 5B is a drawing of another deposition chamber as described in various representative embodiments.

FIG. 5C is a flow chart of a method for creating an integrated circuit structure using the two deposition chambers of FIGS. 5A and 5B.

FIG. 5D is a flow chart of a method for creating an integrated circuit structure using pasting as described in various representative embodiments.

FIG. 6A is a drawing of still another deposition chamber as described in various representative embodiments.

FIG. 6B is a flow chart of a method for creating an integrated circuit structure using a shield as described in various representative embodiments.

FIG. 7A is a drawing of a cross-section of even still another integrated circuit structure as described in various representative embodiments.

FIG. 7B is a flow chart of a method for creating an integrated circuit structure using a thin antireflective coating as described in various representative embodiments.

FIG. 8 is a flow chart of a method for creating an integrated circuit structure using lower temperature tungsten deposition as described in various representative embodiments.

### DETAILED DESCRIPTION

As shown in the drawings for purposes of illustration, novel techniques which can be integrated into existing integrated circuit (IC) processes that use aluminum/tungsten (Al/W) based metallization systems are disclosed herein. These techniques enable maintaining small values of leakage currents while controlling the variability of contact resistances and leakage currents over large area arrays. The leakage currents of interest typically comprise p-n junction diode leakage.

An antireflective (AR) coating included on top of the interconnection (metallization) layers for most advanced integrated circuit processes having 0.35 micron or smaller geometries improves the lithography process margin in patterning smaller features in the integrated circuit. The inclusion of this antireflective coating reduces pattern dispersion during exposure of the interconnect layer photoresist, thereby producing a sharper image pattern resulting in improved definition of interconnect features. Typically for aluminum/tungsten based metallization systems, a flash titanium layer (flash Ti) is applied between the aluminum (Al) and the antireflective layer. This antireflective coating is generally titanium nitride (TiN). Tungsten (W) is used to fill the vias that interconnect the layers of aluminum. The flash titanium layer generally prevents a broad distribution of contact resistance which would otherwise result from the formation of aluminum nitride (AlN) during the deposition of the top antireflective titanium nitride and subsequent exposure of the wafer to nitrogen plasma during resist ash steps.

It is important that the titanium be consumed by the underlying layer of aluminum during the subsequent thermal processing. As the consumption of the titanium by the aluminum is inhibited by the unintentional titanium nitride layer, there is a need to eliminate or reduce the effect of this unintentional titanium nitride layer. In the following detailed description and in the several figures of the drawings, like elements are identified with like reference numerals.

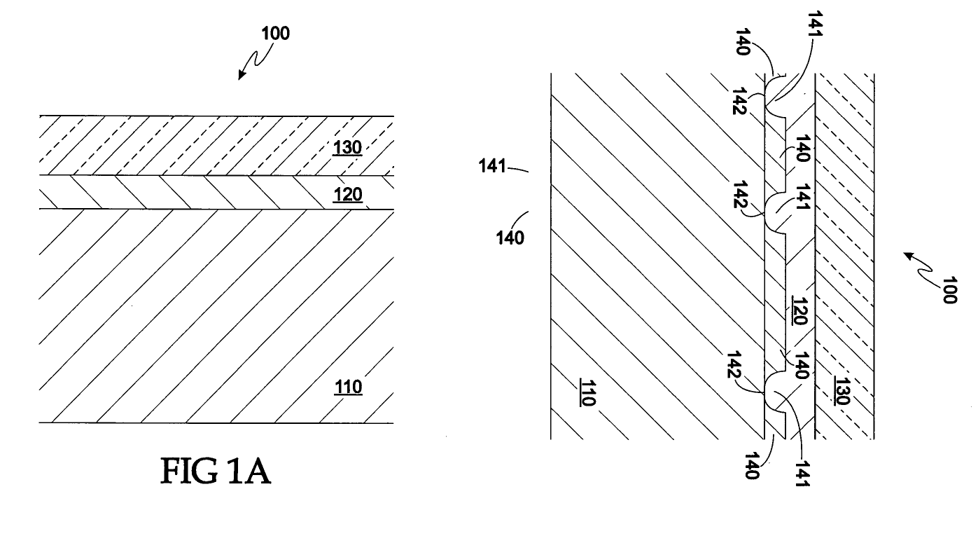

FIG. 1A is a drawing of a cross-section of part of an integrated circuit structure 100 as described in various representative embodiments. In FIG. 1A, the part of the integrated circuit structure 100 comprises an interconnect conductor 110, also referred to herein as an interconnect layer 110, an initiation layer 120, and an antireflective layer 130. The initiation layer 120 lies on top of the interconnect conductor 110, and the antireflective layer 130 lies on top of the initiation layer 120. In this representative example of FIG. 1A, the interconnect conductor 110 is aluminum and as such is referred to as aluminum layer 110, and the initiation layer 120 is also referred to as flash titanium layer 120. In the representative example of FIG. 1A, the antireflective layer 130 is titanium nitride. FIG. 1A and other drawings herein are for illustrative purposes only and are not drawn to scale.

For processes in which the interconnect conductor 110 is aluminum, the initiation layer 120 is titanium, and the antireflective layer 130 is titanium nitride. In which case, the flash titanium layer 120 and the antireflective layer 130 are typically deposited one after the other in the same chamber. Starting from a clean titanium target, the first wafer receives a cleanly sputtered layer of titanium, the initiation layer 120 which is referred to as the flash titanium layer 120 or the titanium initiation layer 120. Nitrogen gas is then turned on in the chamber while titanium sputtering continues resulting in the deposition of titanium nitride on the wafer. The result of this process for the first wafer is shown in FIG. 1A.

FIG. 1B is a drawing of a cross-section of another integrated circuit structure 100 as described in various representative embodiments. In the representative embodiment of FIG. 1B, the part of the integrated circuit structure 100 comprises the interconnect conductor 110, an inhibiting layer 140, the initiation layer 120, and the antireflective layer 130. The inhibiting layer 140 lies on top of the interconnect conductor 110, the initiation layer 120 lies on top of the inhibiting layer 140, and the antireflective layer 130 lies on top of the initiation layer 120. In this representative example of FIG. 1B, the interconnect conductor 110 is aluminum, the initiation layer 120 is flash titanium, the inhibiting layer 140 is unintentional titanium nitride which is then referred to as unintentional titanium nitride layer 140, and the antireflective layer 130 is titanium nitride.

At the same time that titanium nitride is being deposited onto the wafer, titanium nitride is also being formed on the titanium target. As such, during subsequent wafer processing, instead of initially sputtering titanium from the titanium target, titanium nitride is initially sputtered followed by titanium once the titanium nitride formed on the target from the previous wafer processing has been removed. Thus, subsequent to the first wafer processed in the chamber with a clean target, the wafers will first receive an unintentional layer of titanium nitride and then a layer of titanium before the nitrogen gas is turned on. This layer of titanium nitride is a few atomic layers thick and is not very uniform in thickness across the top of the aluminum. The result of this process for wafers subsequent to the first wafer is shown in FIG. 1B. Due to the non-uniformity and thinness of the unintentional titanium nitride layer 140, it will have locations in which holes 141 in the film exist. As such, the flash titanium layer 120 and the aluminum layer 110 will be in contact at boundaries 142.

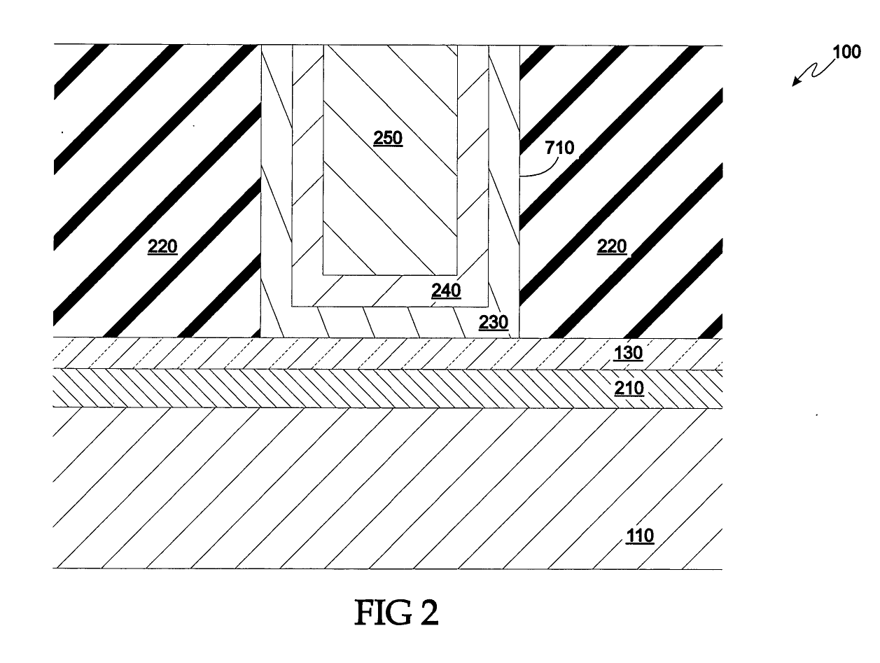

FIG. 2 is a drawing of a cross-section of still another integrated circuit structure 100 as described in various representative embodiments. In the representative embodiment of FIG. 2, the initial steps used to construct or fabricate the integrated circuit structure 100 are the same as those used to fabricate the integrated circuit metallization structure 100 of FIG. 1A. Following the construction of the integrated circuit structure 100 of FIG. 1A which includes the initiation layer 120 and the antireflective layer 130 on top of the interconnect conductor 110, the flash titanium layer 120 is reacted with the aluminum layer 110 to create reacted layer 210 which in the representative embodiment of FIG. 2 is titanium aluminide (TiAl₃) layer 210. Again, this structure would be the result of processing the first wafer in the titanium sputtering chamber. Following these processing steps and after a contact window 710 has been opened in dielectric layer 220 disposed over the antireflective layer 130 and shown in FIG. 2 as SiO₂ layer 220, a seed titanium layer 230, a seed titanium nitride layer 240, and a tungsten plug layer 250 are sequentially deposited to form an interconnection through the contact window 710 or via 710 to the next interconnect layer 110. Prior to the formation of this interconnection, however, the wafer receives a tungsten polish. The tungsten polish is typically a chemical mechanical polish which removes those parts of the tungsten plug layer 250, the seed titanium nitride layer 240, and the seed titanium layer 230 that overlie the dielectric layer 220. The integrated circuit structure 100 is then as shown in FIG. 2 with essentially the only remaining tungsten from the tungsten plug layer 250 residing in the contact window 710. That remaining part of the tungsten plug layer 250 is now referred to as the tungsten plug 250.

The purpose of the seed titanium layer 230 is to getter any oxide from the top of the aluminum layer 110 at the bottom of the contact via so as to make a good electrical contact to the aluminum layer 110. The seed titanium layer 230 also aids in providing good adhesion between the tungsten plug 250 and dielectric layer 220 exposed on the sidewall of the contact via as tungsten does not adhere well to silicon dioxide.

The purpose of the seed titanium nitride layer 240 is to protect the seed titanium layer 230 from attack by processing components during tungsten plug 250 deposition. The seed titanium nitride layer 240 also provides electrical contact between the titanium nitride layer 240 and the tungsten plug 250.

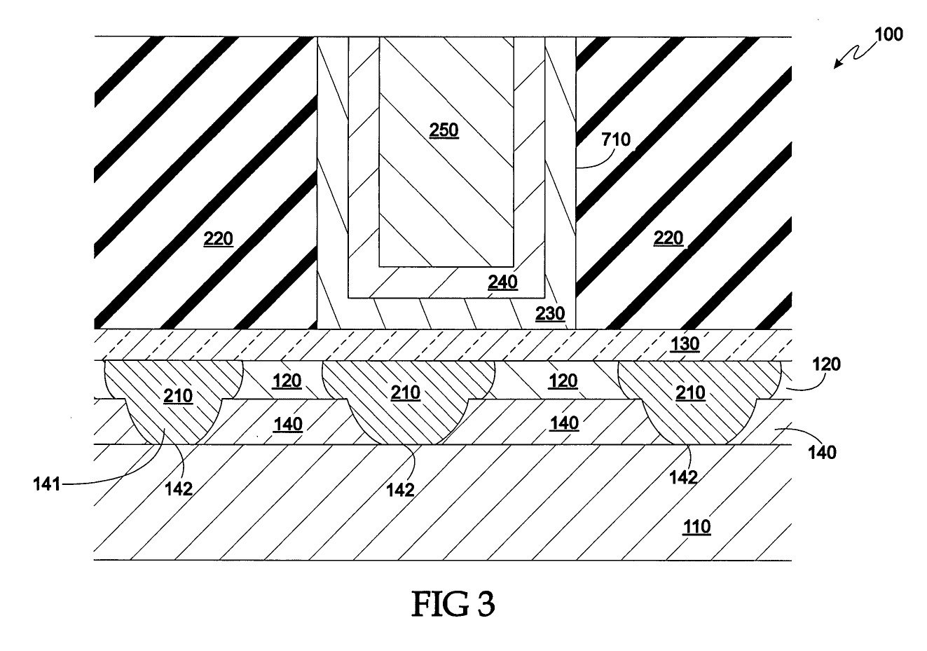

FIG. 3 is a drawing of a cross-section of yet another integrated circuit structure 100 as described in various representative embodiments. In the representative embodiment of FIG. 3, the initial steps used to construct or fabricate the integrated circuit structure 100 are the same as those used to fabricate the integrated circuit structure 100 of FIG. 1B. Following the construction of the integrated circuit structure 100 of FIG. 1B, subsequent processing intended to react the flash titanium layer 120 with the aluminum layer 110 to create a reacted layer 210 as the titanium aluminide (TiAl₃) layer 210 of FIG. 2 is, however, inhibited by the unintentional titanium nitride layer 140 in those locations where it is sufficiently thick. In other locations where the unintentional titanium is not thick enough, it will react with the aluminum to form titanium aluminide.

As discussed with respect to FIG. 1B, the unintentional titanium nitride layer 140 is only a few atomic layers thick and non-uniform in thickness across the top surface of the aluminum layer 110. Due to the non-uniformity and thinness of the unintentional titanium nitride layer 140, it will have locations in which holes 141 in the film exist. As such, the flash titanium layer 120 and the aluminum layer 110 will be in contact at boundaries 142. At these boundaries 142, subsequent processing reacts the titanium in the flash titanium layer 120 with the aluminum in the aluminum layer 110 to create the titanium aluminide layer 210 which is also non-uniform in extent and thickness across the top surface of the aluminum layer 110. It is effectively in those locations where holes 141 exist in the unintentional titanium nitride layer 140 that titanium from the flash titanium layer 120 can react with the aluminum in the interconnect conductor 110 to tie up the free titanium in the flash titanium layer 120 thereby forming titanium aluminide.

Following these processing steps and after a contact window 710 has been opened in the dielectric layer 220 disposed over the antireflective layer 130 and shown in FIG. 3 as SiO₂ layer 220, the seed titanium layer 230, the seed titanium nitride layer 240, and the tungsten plug layer 250 are sequentially deposited to form an interconnection through the contact window 710 or via 710 to the next interconnect layer 110. Prior to the formation of this interconnection, however, the wafer receives a tungsten polish. The tungsten polish is again typically a chemical mechanical polish which removes those parts of the tungsten plug layer 250, the seed titanium nitride layer 240, and the seed titanium layer 230 that overlie the dielectric layer 220. The integrated circuit structure 100 is then as shown in FIG. 3 with essentially the only remaining tungsten from the tungsten plug layer 250 residing in the contact window 710. Once again, that remaining part of the tungsten plug layer 250 is now referred to as the tungsten plug 250.

The presence of the unintentional titanium nitride layer 140 results in increased gettering of hydrogen from the SiO₂ layer 220 by the unreacted flash titanium layer 120. The hydrogen gettered from the surrounding oxides and other layers creates a concentration gradient of hydrogen down to the silicon (Si) diode surface. This gettering pulls hydrogen that otherwise would have satisfied dangling bonds at the silicon/silicon dioxide interface. As such, an increased number of interface states are left at that interface resulting in an increase in leakage current.

So, in order to reduce leakage currents, it is important to keep hydrogen attached to these dangling bonds. Forming titanium aluminide ties up the free titanium thereby preventing it from gettering hydrogen which would otherwise result in a higher defect density at the silicon/silicon-dioxide interface. Again, the cause of these difficulties is due to the fact that the flash titanium layer 120 is typically deposited in the same chamber as the antireflective layer 130 is deposited which results in the unintentional titanium nitride layer 140 interposed between the aluminum layer 110 and the flash titanium layer 120. Subsequent thermal steps are typically unable to convert all of the titanium in the flash titanium layer 120 with aluminum from the aluminum layer 110 to form titanium aluminide due to the presence of the unintentional titanium nitride layer 140. Any remaining free titanium can then getter hydrogen from the surrounding oxides resulting in leakage currents that are greater than would have otherwise existed had all the titanium been converted into titanium aluminide.

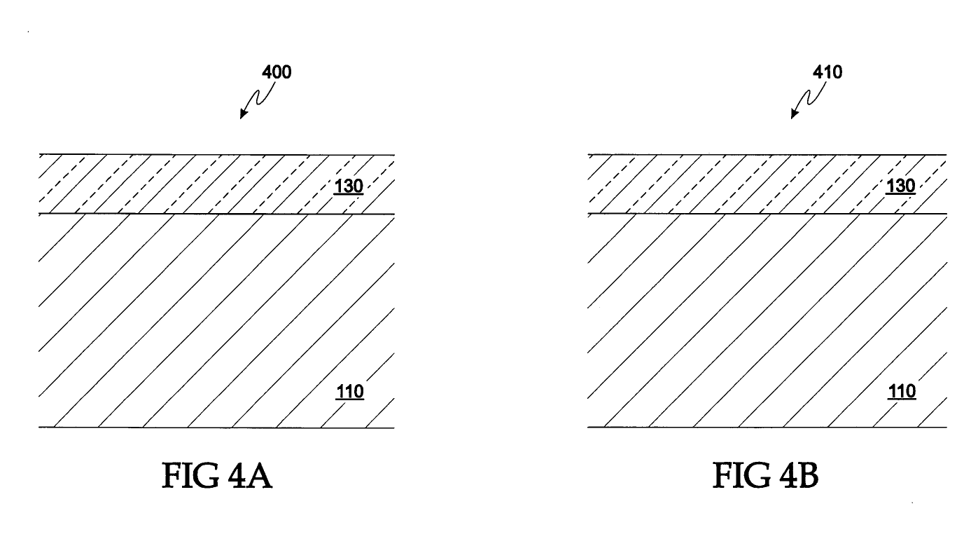

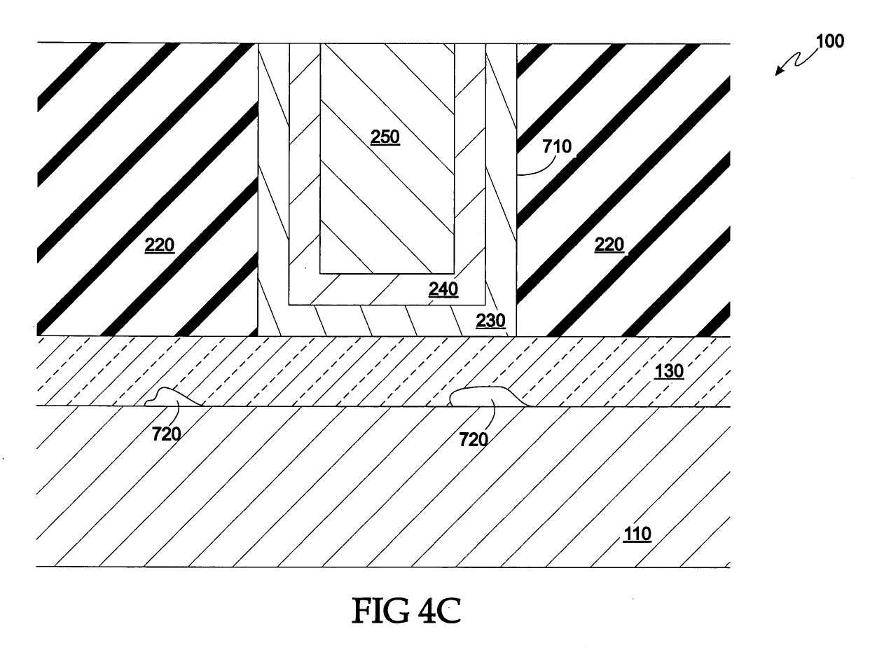

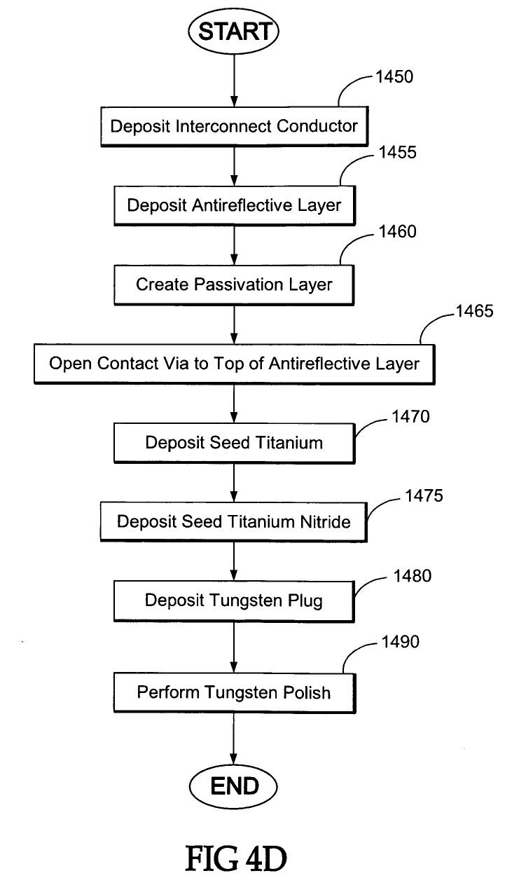

FIG. 4A is a drawing of a cross-section of an integrated circuit top interconnect layer 400 as described in various representative embodiments. In the example of FIG. 4A, the integrated circuit top interconnect layer 400 comprises the aluminum layer 110 and the antireflective layer 130, but not the flash titanium layer 120. As the flash titanium layer 120 is absent, so also is the unintentional titanium nitride layer 140. Since this is the top interconnect layer 110, by default there is not a tungsten plug 250 on top of this layer and no contacts are made to this layer from above. Thus, there is not an issue with increased contact resistance or large variations in contact resistance across the wafer even though aluminum nitride is formed during deposition of the antireflective layer 130 and subsequent exposure of the wafer to nitrogen plasma during resist ash steps. In addition, normally the aluminum and titanium react during subsequent tungsten plug 250 deposition or subsequent high temperature thermal steps. But, for the final, top interconnect layer 100 there is no subsequent plug deposition and typically only one subsequent high temperature step is left in the process flow. This final high temperature step is the final anneal. Final anneal generally occurs in a temperature range of 390-420 degrees centigrade. As such, final anneal is typically insufficient to completely react the titanium with the aluminum. Thus, removal of the flash titanium step for the top interconnect layer does not present additional problems as the situation is not made worse with respect to the gettering of hydrogen with the associated increase in leakage current since free titanium is not present to provide such gettering.

FIG. 4B is a drawing of a cross-section of an integrated circuit underlying interconnect layer 410 as described in various representative embodiments. In the representative embodiment of FIG. 4B, the integrated circuit underlying interconnect layer 410 comprises the interconnect conductor (aluminum layer) 110 and the antireflective layer 130, but not the flash titanium layer 120. The antireflective layer 130 is typically between 150 and 650 angstroms thick. As the flash titanium layer 120 is absent, so also is the unintentional titanium nitride layer 140. However, for the underlying interconnect layers 410 the flash titanium layer 120 cannot just be eliminated as this would result in a broad distribution of contact resistance due to the presence of aluminum nitride at the bottom of the contact. In order to get around this issue, the contact etch is stopped at the top of the thicker (typically 350 to 650 angstroms) antireflective layer 130, i.e., the top of the titanium nitride. This is achieved by using an etch chemistry that has a high selectivity, i.e., the etch rate of oxide is significantly larger than the etch rate of titanium nitride. In this scheme, the flash titanium layer 120 is eliminated. The thicker remaining titanium nitride after contact etch also ensures that there is no further aluminum nitride formation during subsequent processing steps. While the contact resistance will increase due to the presence of titanium nitride at the bottom of the contact, it does so uniformly across the wafer. Further, since the flash titanium layer 120 is eliminated, there is no remaining free titanium on top of the aluminum layer 110 to getter hydrogen. There is a sufficiently broad contact area to negate the effect of the formation of aluminum nitride in some places.

FIG. 4C is a drawing of a cross-section of an integrated circuit structure 100 having the integrated circuit underlying interconnect layer 410 of FIG. 4B. In the representative embodiment of FIG. 4C, the contact etch has been stopped on top of the antireflective layer 130. The initial steps used to construct or fabricate the integrated circuit structure 100 of FIG. 4C are the same as those used to fabricate the integrated circuit structure 100 of FIG. 4B. Following the construction of the integrated circuit structure 100 of FIG. 4B and subsequent processing which includes deposing the dielectric layer 220 on top over the antireflective layer 130, the contact window 710 is opened in the dielectric layer 220 shown in FIG. 4C as SiO₂ layer 220, the seed titanium layer 230, the seed titanium nitride layer 240, and the tungsten plug layer 250 are sequentially deposited to form an interconnection through the contact window 710 or via 710 to the next interconnect layer 110. Prior to the formation of this interconnection, however, the wafer receives a tungsten polish. The tungsten polish is again typically a chemical mechanical polish which removes those parts of the tungsten plug layer 250, the seed titanium nitride layer 240, and the seed titanium layer 230 that overlie the dielectric layer 220. The integrated circuit structure 100 is then as shown in FIG. 4C with essentially the only remaining tungsten from the tungsten plug layer 250 residing in the contact window 710.. Once again, that remaining part of the tungsten plug layer 250 is now referred to as the tungsten plug 250.

Also shown in FIG. 4C are uneven aluminum nitride regions 720 which were formed during titanium nitride deposition, as well as subsequent resist ash steps.

FIG. 4D is a flow chart of a method for creating an integrated circuit structure 100 having the integrated circuit underlying interconnect layer 410 of FIG. 4B. In block 1450 of FIG. 4D, the interconnect conductor 110 is deposited on top of other features on the semiconductor substrate. Block 1450 then transfers control to block 1455.

In block 1455, the antireflective layer 130 is deposited on top of the interconnect conductor 110. Block 1450 then transfers control to block 1460.

In block 1460, other processing steps are performed including the creation of the dielectric layer 220. Block 1460 then transfers control to block 1465.

In block 1465, a contact via, also referred to as a contact window, is etched in the dielectric layer 220 which stops on top of the antireflective layer 130. The contact via is etched using a high selectivity etch for which the silicon dioxide etch rate is significantly larger than titanium nitride etch rate. Block 1465 then transfers control to block 1470.

In block 1470, the seed titanium layer 230 is deposited. Block 1470 then transfers control to block 1475.

In block 1475, the seed titanium nitride layer 240 is deposited. Block 1475 then transfers control to block 1480.

In block 1480, the tungsten plug 250 is deposited. Block 1480 then transfers control to block 1490.

In block 1490, the tungsten, titanium nitride, and titanium in regions other than the tungsten plug regions are removed by using chemical mechanical polishing in a process typically referred to as a tungsten polish. Block 1490 then terminates the process.

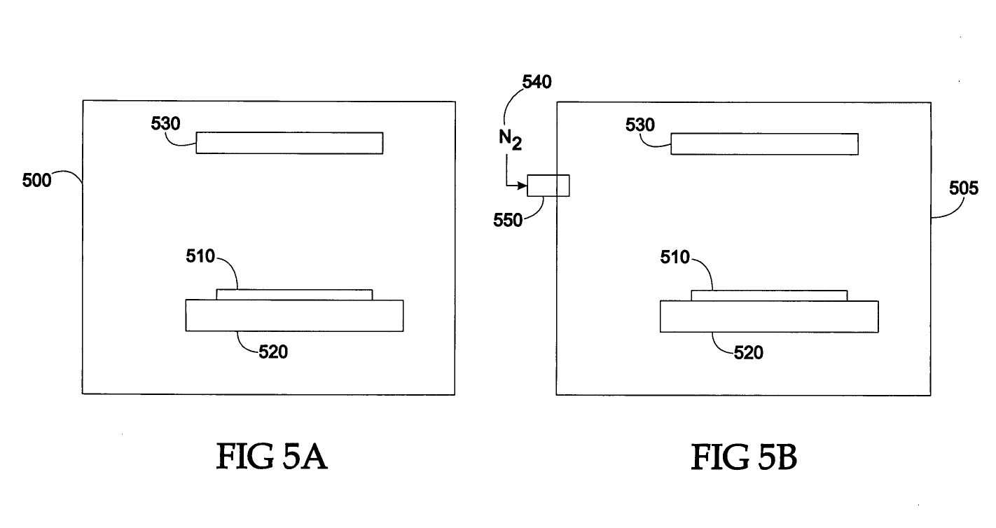

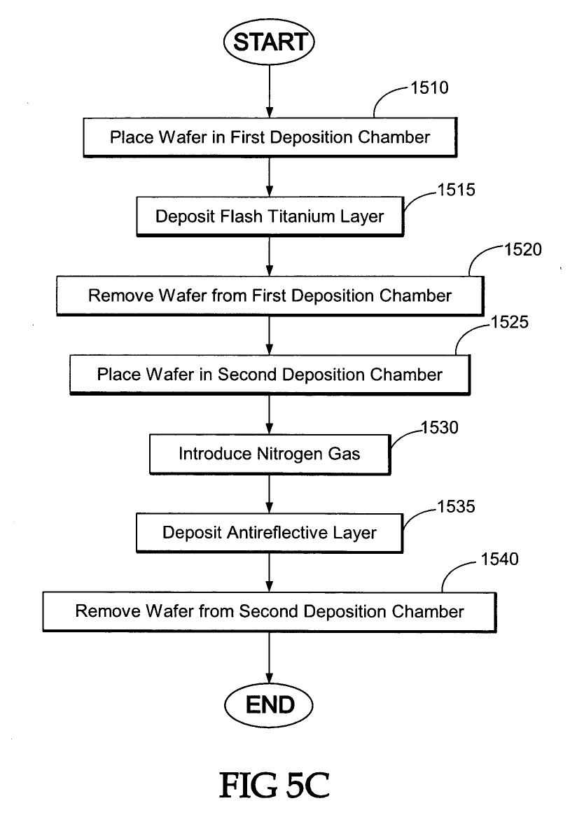

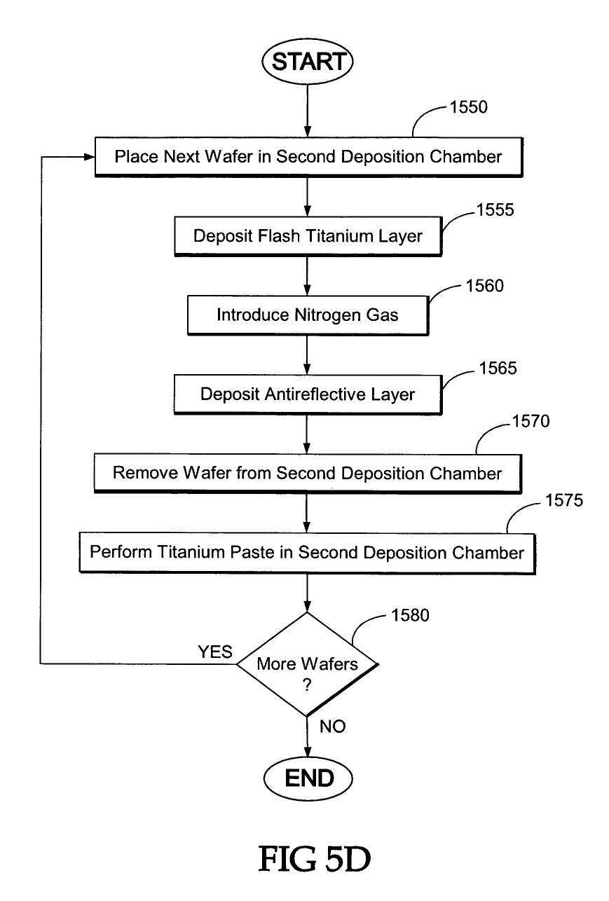

FIG. 5A is a drawing of a deposition chamber as described in various representative embodiments. FIG. 5B is a drawing of another deposition chamber as described in various representative embodiments. Included in FIG. 5A is a first deposition chamber 500, which in representative embodiments is a flash titanium deposition chamber 500, and included in FIG. 5B is a second deposition chamber 505, which in representative embodiments is a titanium nitride deposition chamber 505. Both first and second deposition chambers 500,505 comprise targets 530 which in representative embodiments are titanium targets 530. The titanium nitride deposition chamber 505 includes a gas port 550 by which a gas such as nitrogen gas 540 is introduced into the titanium nitride deposition chamber 505. Also shown in each of the deposition chambers 500,505 is a wafer 510 supported on a chuck 520. Not shown in any of the figures are means for introducing argon gas into the chambers 500,505 which is used in the sputtering of titanium during the deposition of both titanium and titanium nitride.

In the flash titanium deposition chamber 500 the flash titanium layer 120 is deposited onto the surface of the wafer 510, whereas in the titanium nitride deposition chamber 505 the antireflective layer 130 is deposited onto the surface of the wafer 510. A given wafer 510 is first placed in the flash titanium deposition chamber 500, the titanium target 530 sputters flash titanium layer 120 onto the wafer 510, the wafer is removed from the flash titanium deposition chamber 500 and placed in the titanium nitride deposition chamber 505, nitrogen gas 540 is introduced into the titanium nitride deposition chamber 505 via port 550, and then in the presence of the nitrogen gas 540 the titanium target 530 sputters the antireflective layer 130 onto the wafer 510. When the wafer 510 is removed from the titanium nitride deposition chamber 505, the wafer 510 will be in the condition of FIG. 1A. In other words, the wafer 510 will not have the unintentional titanium nitride layer 140 deposited on it. In this way, the target 530 and walls of the flash titanium deposition chamber 500 are not contaminated with titanium nitride.

FIG. 5C is a flow chart of a method for creating an integrated circuit structure 100 using the two deposition chambers of FIGS. 5A and 5B. In block 1510 of FIG. 5C, the wafer 510 is placed in the flash titanium deposition chamber 500 of FIG. 5A. Block 1510 then transfers control to block 1515.

In block 1515, the flash titanium layer 120 is deposited on top of the interconnect conductor 110 on the wafer 510 in the flash titanium deposition chamber 500. Block 1515 then transfers control to block 1520.

In block 1520, the wafer 510 is removed from the flash titanium deposition chamber 500 of FIG. 5A. Block 1520 then transfers control to block 1525.

In block 1525, the wafer 510 is placed in the titanium nitride deposition chamber 505 of FIG. 5B. Block 1525 then transfers control to block 1530.

In block 1530, nitrogen gas 540 is introduced into the titanium nitride deposition chamber 505 of FIG. 5B. Block 1530 then transfers control to block 1535.

In block 1535, the antireflective layer 130 is deposited onto the wafer in the titanium nitride deposition chamber 505 of FIG. 5B. Block 1535 then transfers control to block 1540.

In block 1540, the wafer 510 is removed from the titanium nitride deposition chamber 505 of FIG. 5B. Block 1540 then terminates the process.

In another method, the titanium nitride deposition chamber 505 as shown in FIG. 5B is used for depositing both the flash titanium layer 120 and the antireflective layer 130. Once a particular wafer 510 has received the deposition of both the flash titanium layer 120 and the antireflective layer 130 and has been removed from the titanium nitride deposition chamber 505, and before the next wafer 510 is introduced into the titanium nitride deposition chamber 505, the chamber receives a titanium pasting. During the titanium pasting, the target 530 in the titanium nitride deposition chamber 505 is cleared of any titanium nitride residual from the deposition of the antireflective layer 130 on the previous wafer 510. Also at the same time, any residual titanium nitride on the walls and other parts of the titanium nitride deposition chamber 505 which would have been caused by the deposition of the antireflective layer 130 on the previous wafer 510 is covered over. Thus, the next incoming wafer 510 experiences the same chamber environment as the previous wafer 510.

FIG. 5D is a flow chart of a method for creating an integrated circuit structure 100 using pasting as described in various representative embodiments. In block 1550 of FIG. 5D, a wafer 510 is placed in the titanium nitride deposition chamber 505 as shown in FIG. 5B. Block 1550 then transfers control to block 1555.

In block 1555, the flash titanium layer 120 is deposited on top of the interconnect conductor 110 on the wafer 510 in the titanium nitride deposition chamber 505. Block 1555 then transfers control to block 1560.

In block 1560, nitrogen gas 540 is introduced into the titanium nitride deposition chamber 505 of FIG. 5B. Block 1560 then transfers control to block 1565.

In block 1565, the antireflective layer 130 is deposited into the wafer in the titanium nitride deposition chamber 505 of FIG. 5B. Block 1565 then transfers control to block 1570.

In block 1570, the wafer 510 is removed from the titanium nitride deposition chamber 505 of FIG. 5B. Block 1570 then transfers control to block 1575.

In block 1575, the titanium nitride deposition chamber 505 of FIG. 5B is titanium pasted after introducing dummy wafers onto the chuck 520. Titanium pasting includes sputtering the titanium target typically with argon gas for a significant amount of time, such that all residual titanium nitride from the target is cleared leaving only the titanium of the base target material. Block 1575 then transfers control to block 1580.

In block 1580, if there are more wafers 510 to receive the flash titanium layer 120 and the antireflective layer 130, block 1580 transfers control to block 1550. Otherwise, block 1580 terminates the process.

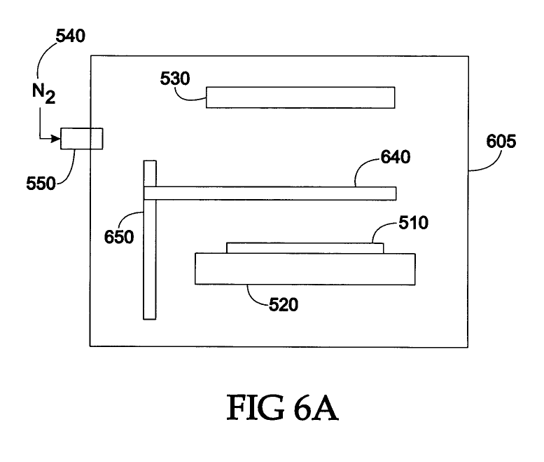

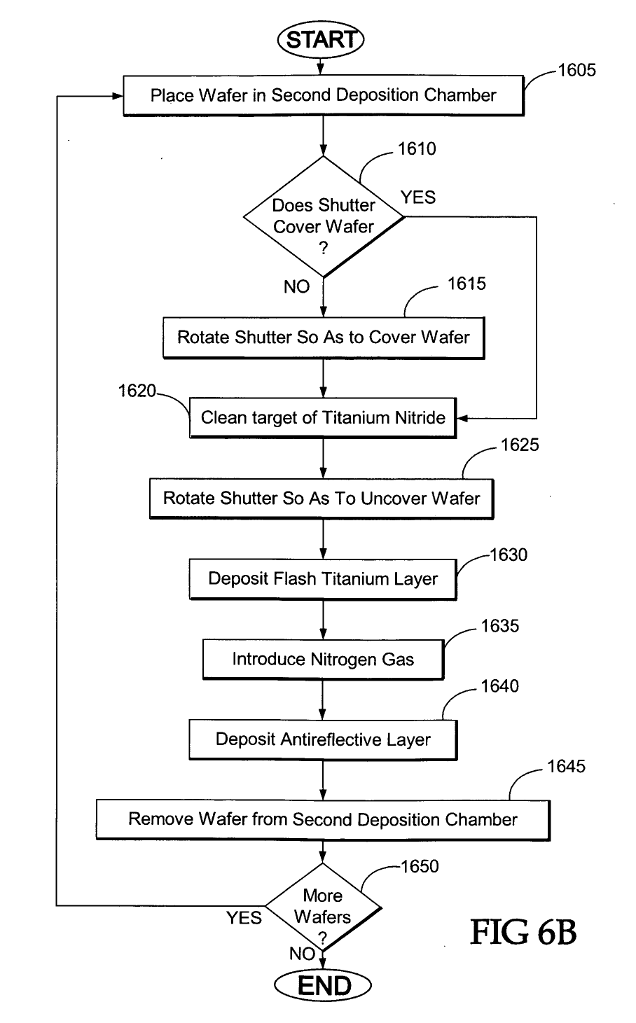

FIG. 6A is a drawing of still another deposition chamber as described in various representative embodiments. In FIG. 6A, a third deposition chamber 605, also referred to herein as a shield deposition chamber 605 comprises target 530 which in the representative embodiment of FIG. 6A is titanium target 530. The shield deposition chamber 605 includes gas port 550 by which nitrogen gas 540 is introduced into the shield deposition chamber 605. Also shown in the shield deposition chamber 605 is the wafer 510 on chuck 520.

Once a new wafer 510 is introduced into the shield deposition chamber 605, a shield 640 which is supported by a post 650 is rotated into a position between the target 530 and the wafer 510 which is situated on the chuck 520. Any titanium nitride remaining on the target 530 from prior processing is then sputtered off while the shield 640 protects the wafer from receiving the unintentional titanium nitride layer 140. Following this cleaning of the target 530, the shield 640 is removed from between the target 530 and the wafer 510, and the flash titanium layer 120 is deposited onto the surface of the wafer 510. And finally nitrogen gas 540 is introduced into the shield deposition chamber 605 and sputtering of the titanium target 530 is initiated in order to deposit the antireflective layer 130 onto the surface of the wafer 510. When the wafer 510 is removed from the titanium nitride deposition chamber 505, the wafer 510 will be in the condition of FIG. 1A. In other words, the wafer 510 will not have the unintentional titanium nitride layer 140 deposited on it.

FIG. 6B is a flow chart of a method for creating an integrated circuit structure 100 using the shield 640 as described in various representative embodiments. In block 1605 of FIG. 6B, a wafer 510 is placed in the shield deposition chamber 605 shown in FIG. 6A. Block 1605 then transfers control to block 1610.

In block 1610, if the shield 640 covers the wafer 510, block 1610 transfers control to block 1620. Otherwise, block 1610 transfers control to block 1615.

In block 1615, the shield 640 is rotated so as to cover the wafer 510. Block 1615 then transfers control to block 1620.

In block 1620, any titanium nitride on the titanium target 530 is removed by sputtering. Block 1620 then transfers control to block 1625.

In block 1625, the shield 640 is rotated so as to uncover the wafer 510. Block 1625 then transfers control to block 1630.

In block 1630, the flash titanium layer 120 is deposited on top of the interconnect conductor 110 on the wafer 510 in the shield deposition chamber 605. Block 1630 then transfers control to block 1635.

In block 1635, nitrogen gas 540 is introduced into the shield deposition chamber 605. Block 1635 then transfers control to block 1640.

In block 1640, the antireflective layer 130 is deposited into the wafer in the shield deposition chamber 605. Block 1640 then transfers control to block 1645.

In block 1645, the wafer 510 is removed from the shield deposition chamber 605. Block 1645 then transfers control to block 1650.

In block 1650, if there are more wafers 510 to receive the flash titanium layer 120 and the antireflective layer 130, block 1650 transfers control to block 1605. Otherwise, block 1650 terminates the process.

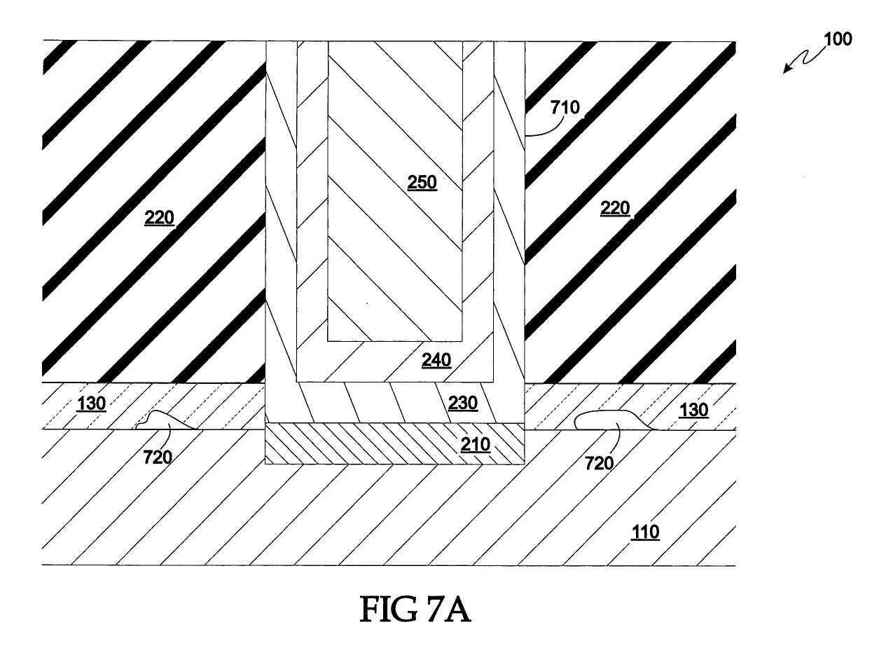

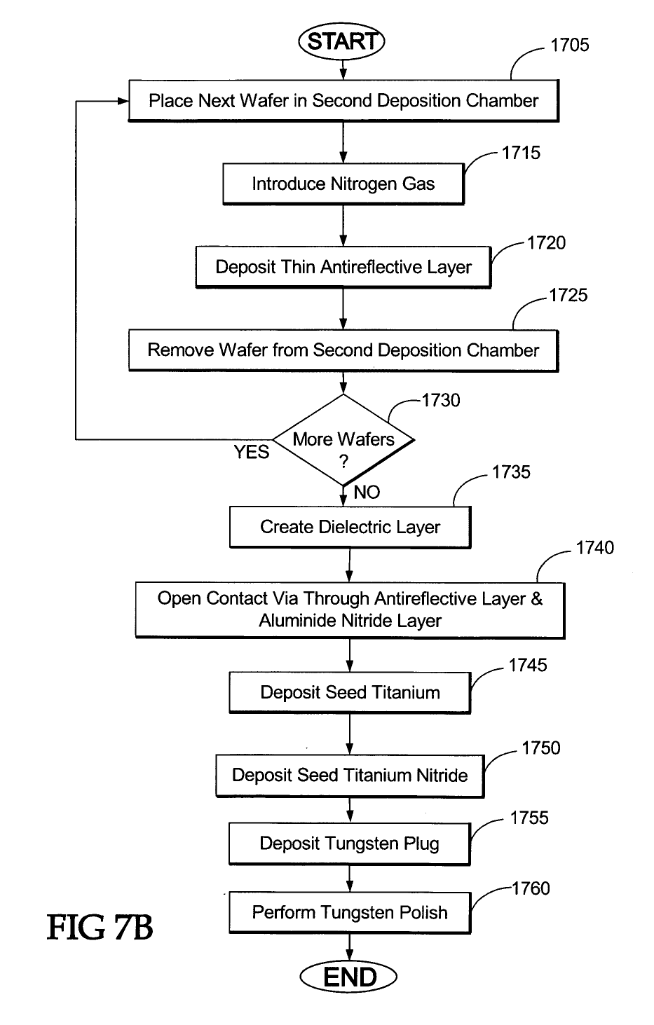

FIG. 7A is a drawing of a cross-section of even still another integrated circuit structure 100 as described in various representative embodiments. In FIG. 7A, the antireflective layer 130 is thinner than would otherwise be used and there is no flash titanium layer 120. The absence of the flash titanium layer 120 and thinner titanium nitride layer results in the formation of thicker aluminum nitride regions 720 during titanium nitride deposition, as well as subsequent resist ash steps. However, a thinner antireflective layer 130 enables the contact etch to etch through the titanium nitride of the antireflective layer 130, as well as the aluminum nitride region 720 reaching into the aluminum. The aluminum nitride formed is physically sputtered away in contact window 710 which removes any problems with what would otherwise be the broad contact resistance distribution issue. Low leakage current can be obtained by ensuring that the titanium is not free titanium but is in the form of titanium aluminide in contact window 710. In FIG. 7A, the contact window 710, also referred to herein as a contact via 710, is shown as having been etched all the way to the aluminum layer 110. Titanium from the seed titanium layer 230 is then reacted with the aluminum layer 110 to form the titanium aluminide layer 210 during subsequent process steps.

FIG. 7A shows the integrated circuit metallization structure 100 following disposing of the dielectric layer 220 on top over the antireflective layer 130 and the opening of the contact window 710 in the opening in the dielectric layer 220 which is shown in FIG. 7A as SiO₂ layer 220. Also, the seed titanium layer 230, the seed titanium nitride layer 240, and the tungsten plug layer 250 have been sequentially deposited to form an interconnection through the contact window 710 or via 710 to the next interconnect layer 100. Prior to the formation of this interconnection, however, the wafer receives a tungsten polish. The tungsten polish is again typically a chemical mechanical polish which removes those parts of the tungsten plug layer 250, the seed titanium nitride layer 240, and the seed titanium layer 230 that overlie the dielectric layer 220. The integrated circuit structure 100 is then as shown in FIG. 7A with essentially the only remaining tungsten from the tungsten plug layer 250 residing in the contact window 710. Once again, that remaining part of the tungsten plug layer 250 is now referred to as the tungsten plug 250.

FIG. 7B is a flow chart of a method for creating an integrated circuit structure 100 using a thin antireflective coating as described in various representative embodiments. In block 1705 of FIG. 7B, a wafer 510 is placed in the second deposition chamber 505 as shown in FIG. 5B. Block 1705 then transfers control to block 1715.

In block 1715, nitrogen gas 540 is introduced into the second deposition chamber 505 of FIG. 5B. Block 1715 then transfers control to block 1720.

In block 1720, a thin antireflective layer 130 which is typically in the range of 150 to 650 angstroms is deposited onto the wafer in the second deposition chamber 505 of FIG. 5B. Block 1720 then transfers control to block 1725.

In block 1725, the wafer 510 is removed from the second deposition chamber 505 of FIG. 5B. Block 1725 then transfers control to block 1730.

In block 1730, if there are more wafers 510 to receive the antireflective layer 130, block 1730 transfers control to block 1705. Otherwise, block 1730 then transfers control to block 1735.

In block 1735, other processing steps are performed including the creation of the dielectric layer 220. Block 1735 then transfers control to block 1740.

In block 1740, a contact via 710 is opened in the dielectric layer 220 all the way through the antireflective layer 130 reaching into the aluminum layer 110. Block 1740 then transfers control to block 1745.

In block 1745, the seed titanium layer 230 is deposited. Block 1745 then transfers control to block 1750.

In block 1750, the seed titanium nitride layer 240 is deposited. Block 1750 then transfers control to block 1755.

In block 1755, the tungsten plug 250 is deposited. Block 1755 then transfers control to block 1760.

In block 1760, the tungsten, titanium nitride, and titanium in regions other than the tungsten plug regions are removed by using chemical mechanical polishing in a process typically referred to as a tungsten polish. Block 1760 then terminates the process.

Tungsten plug deposition, which is generally a chemical vapor deposition (CVD) process, typically occurs at a wafer temperature of 400 Degrees Centigrade or higher. If the wafer temperature is held to less than or equal to 400 degrees centigrade, there will be less hydrogen gettering by the seed titanium layer 230 as compared with a higher temperature of tungsten deposition. During tungsten deposition, the seed titanium layer 230 covers all the areas of the wafer and is free titanium. As such, it has a significant surface area for gettering hydrogen. The lower the temperature of tungsten deposition, the smaller the amount of hydrogen that is lost from the silicon/silicon dioxide interface. As previously stated, this condition enhances the hydrogen passivation of dangling bond defects at the silicon/silicon oxide interface and, thereby, reduces the leakage current. However, a lower tungsten deposition temperature also reduces the rate of titanium aluminum reaction to form titanium aluminide. In addition, the lower tungsten deposition temperature reduces the tungsten deposition rate with associated resultant lower throughput and increases stress in the wafer. For these reasons, tungsten deposition temperature cannot be arbitrarily lowered but is typically held to between 385 and 415 degrees centigrade. The resulting structure would be as shown in FIG. 2.

It has been found that the leakage current increases above a tungsten plug deposition temperature of 400 degrees centigrade. It is believed that the dielectric layers on top of the silicon have a significant amount of hydrogen all the way to the silicon surface. As such, if the temperature is very high, during tungsten plug deposition there will be greater gettering of the hydrogen than otherwise. The diffusion of hydrogen in oxide and its gettering by titanium are both thermally activated processes. As such, the rates for both of these processes increase significantly with temperature.

During tungsten deposition, titanium on the side-walls of the tungsten plugs 250, as well as on dielectric layer 220 areas, has no aluminum to react with. As such, these areas act like sources of hydrogen gettering. They take away some of the hydrogen that would otherwise combine with the dangling bonds at the silicon/silicon dioxide interface. This condition results in a higher leakage current. So, if the temperature of tungsten deposition drops to 400 degrees centigrade or below, the rate of hydrogen diffusion is slower which results in a lower leakage current.

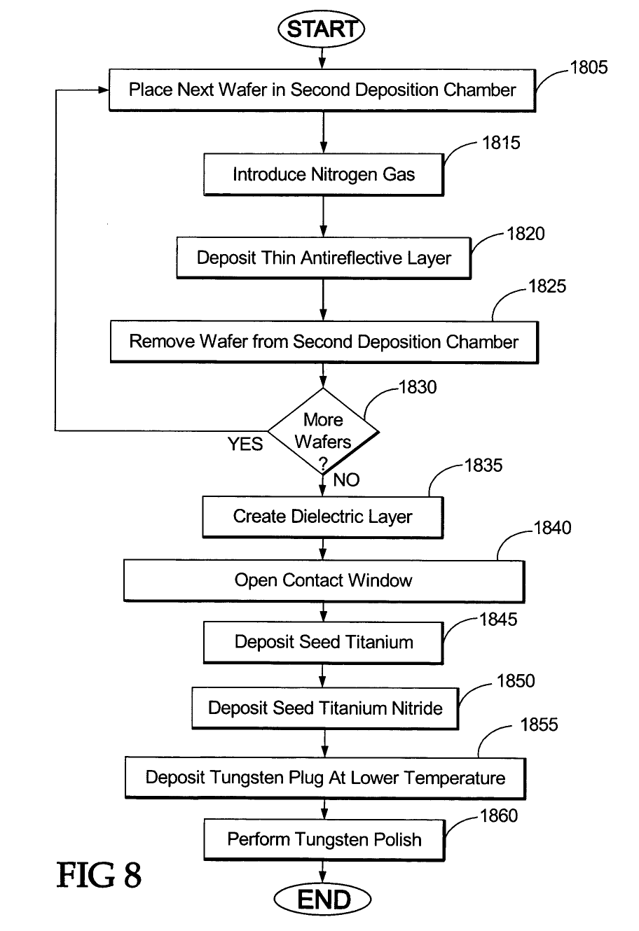

FIG. 8 is a flow chart of a method for creating an integrated circuit structure 100 using lower temperature tungsten deposition as described in various representative embodiments. In block 1805 of FIG. 8, a wafer 510 is placed in the second deposition chamber 505 as shown in FIG. 5B. Block 1805 then transfers control to block 1815.

In block 1815, nitrogen gas 540 is introduced into the second deposition chamber 505 of FIG. 5B. Block 1815 then transfers control to block 1820.

In block 1820, the antireflective layer 130 is deposited into the wafer in the second deposition chamber 505 of FIG. 5B. Block 1820 then transfers control to block 1825.

In block 1825, the wafer 510 is removed from the second deposition chamber 505 of FIG. 5B. Block 1825 then transfers control to block 1830.

In block 1830, if there are more wafers 510 to receive the antireflective layer 130, block 1830 transfers control to block 1805. Otherwise, block 1830 then transfers control to block 1835.

In block 1835, other processing steps are performed including the creation of the dielectric layer 220. Block 1835 then transfers control to block 1840.

In block 1840, a contact via 710 is opened in the dielectric layer 220. Block 1840 then transfers control to block 1845.

In block 1845, the seed titanium layer 230 is deposited. Block 1845 then transfers control to block 1850.

In block 1850, the seed titanium nitride layer 240 is deposited. Block 1850 then transfers control to block 1855.

In block 1855, the tungsten plug 250 is deposited at a deposition temperature of a lower temperature which is typically between 385 and 415 degrees centigrade. Block 1855 then transfers control to block 1860.

In block 1860, the tungsten, titanium nitride, and titanium in regions other than the tungsten plug regions are removed by using chemical mechanical polishing in a process typically referred to as a tungsten polish. Block 1860 then terminates the process.

In summary, representative embodiments of processing methods which can be integrated into existing integrated circuit processes that use aluminum/tungsten based metallization systems which enable small values of leakage currents while controlling the variability of contact resistance and leakage current over large area arrays are disclosed herein.

An antireflective (AR) coating or layer included on top of each metallization layer for most advanced integrated circuit processes having 0.35 micron or smaller geometries provides a sharper definition of interconnect pattern. The inclusion of this antireflective coating has been found to reduce pattern dispersion during exposure of the interconnect layer photoresist, thereby producing a sharper resist pattern which results in the sharper interconnect pattern. Typically for these aluminum/tungsten based metallization systems, a flash titanium layer is applied between the aluminum and the antireflective layer which is generally titanium nitride. Tungsten is used to interconnect the layers of aluminum interconnection. It has also been found that the flash titanium layer generally prevents a broad distribution of contact resistance which would otherwise result by the formation of aluminum nitride during the deposition of the top antireflective titanium nitride and subsequent exposure of the wafer to nitrogen plasma during resist ash steps.

In order to reduce leakage current, it is important that the titanium be consumed by the underlying layer of aluminum in forming titanium aluminide. As the consumption of the titanium by the aluminum is inhibited by the unintentional titanium nitride layer, it is important to eliminate or reduce the effect of this unintentional titanium nitride layer. Representative embodiments disclosed herein provide such techniques.

The representative embodiments, which have been described in detail herein, have been presented by way of example and not by way of limitation. It will be understood by those skilled in the art that various changes may be made in the form and details of the described embodiments resulting in equivalent embodiments that remain within the scope of the appended claims.

What is claimed is:

1. A method for fabricating a low leakage integrated circuit structure, comprising:
disposing an antireflective layer without intervening layers directly onto the top of an interconnect conductor, wherein the interconnect conductor comprises aluminum, wherein the antireflective layer comprises titanium nitride, and wherein the antireflective layer has thickness less than or equal to 650 angstroms and greater than or equal to 150 angstroms;
disposing a dielectric layer over the antireflective layer; and
opening a contact window, wherein the contact window extends at least down to the antireflective layer.

2. The method as recited in claim 1, following the step opening the contact window, the steps further comprising:
disposing a seed titanium layer over the dielectric layer, wherein the seed titanium layer makes contact with the interconnect conductor through the contact window;
disposing a seed titanium nitride layer over the seed titanium layer, wherein the seed titanium nitride layer makes contact with the seed titanium layer through the contact window;
disposing a tungsten plug layer over the seed titanium nitride layer, wherein the tungsten plug layer makes contact with the seed titanium nitride layer through the contact window; and
performing a tungsten polish, wherein the tungsten polish removes those parts of the seed titanium layer, the seed titanium nitride layer, and the tungsten plug layer overlying the dielectric layer.

3. The method as recited in claim 1, wherein the interconnect conductor is underlying interconnect layer and wherein the contact window does not extend through the antireflective layer.

4. The method as recited in claim 3, wherein the step disposing the antireflective layer comprises introducing nitrogen gas into a deposition chamber and sputtering a titanium target in the deposition chamber.

5. The method as recited in claim 1, wherein the contact window extends through any aluminum nitride region formed during disposition of the antireflective layer and other steps prior to opening the contact window.

6. The method as recited in claim 5, wherein the step disposing the antireflective layer comprises introducing nitrogen gas into a deposition chamber and sputtering a titanium target in the deposition chamber.

7. The method as recited in claim 5, wherein the dielectric layer comprises silicon dioxide.

8. The method as recited in claim 2, wherein temperature of the integrated circuit structure during disposing of the tungsten plug is greater than or equal to 385 degrees centigrade and is less than or equal to 415 degrees centigrade.

9. The method as recited in claim 8, wherein the step disposing the antireflective layer comprises introducing nitrogen gas into a deposition chamber and sputtering a titanium target in the deposition chamber.

10. The method as recited in claim 8, wherein the interconnect conductor comprises aluminum.

11. The method as recited in claim 8, wherein the dielectric layer comprises silicon dioxide.

12. An integrated circuit structure, comprising:
an interconnect conductor disposed over other integrated circuit structure, wherein the interconnect conductor comprises aluminum;
an antireflective layer disposed without intervening layers directly onto the top of the interconnect conductor, wherein the antireflective layer comprises titanium nitride and wherein the antireflective layer has thickness less than or equal to 650 angstroms and greater than or equal to 150 angstroms; and
a dielectric layer disposed over the antireflective layer, wherein the dielectric layer comprises a contact window and wherein the contact window extends at least down to the antireflective layer.

13. The integrated circuit structure as recited in claim 12, further comprising:
a seed titanium layer disposed within the contact window;
a seed titanium nitride layer disposed over the seed titanium layer in the contact window; and
a tungsten plug disposed over the seed titanium nitride layer in the contact window.

14. The integrated circuit structure as recited in claim 12, wherein the contact window does not extend through the antireflective layer.

15. The integrated circuit structure as recited in claim 14, wherein the dielectric layer comprises silicon dioxide.

16. The integrated circuit structure as recited in claim 13, wherein the contact window does not extend through the antireflective layer.

17. The integrated circuit structure as recited in claim 16, wherein the dielectric layer comprises silicon dioxide.

18. The integrated circuit structure as recited in claim 12, wherein the contact window extends through the antireflective layer and any aluminum nitride regions formed during disposition of the antireflective layer and prior to opening the contact window.

19. The integrated circuit structure as recited in claim 18, wherein the dielectric layer comprises silicon dioxide.

20. The integrated circuit structure as recited in claim 12, wherein the contact window extends through the antireflective layer and any aluminum nitride regions formed during disposition of the antireflective layer and prior to opening the contact window.

21. The integrated circuit structure as recited in claim 20, wherein the dielectric layer comprises silicon dioxide.

22. A method for fabricating a low leakage integrated circuit structure, comprising:
placing the integrated circuit structure in a deposition chamber, wherein the integrated circuit structure has an interconnect conductor disposed thereon and wherein the interconnect conductor comprises aluminum;
disposing a flash titanium layer without intervening layers directly onto the top of the interconnect conductor;
disposing an antireflective layer over the flash titanium layer, wherein the antireflective layer comprises titanium nitride; and
repeating the above steps for at least one additional integrated circuit structure.

23. The method as recited in claim 22, further comprising:
following the step disposing the flash titanium layer directly onto the top of the interconnect conductor:
removing the integrated circuit structure from the deposition chamber, wherein the deposition chamber is first deposition chamber and
placing the integrated circuit structure in a second deposition chamber.

24. The method as recited in claim 23, wherein the step disposing the flash titanium layer directly onto the interconnect conductor comprises sputtering a titanium target in the first deposition chamber and wherein the step disposing the antireflective layer over the flash titanium layer comprises introducing nitrogen gas into the second deposition chamber and sputtering another titanium target in the second deposition chamber.

25. The method as recited in claim 22, wherein the step disposing the flash titanium layer directly onto the top of the interconnect conductor comprises sputtering a titanium target and
prior to the step disposing the antireflective layer over the flash titanium layer, further comprising:
introducing nitrogen gas into the deposition chamber, wherein disposing the antireflective layer comprises sputtering the titanium target and wherein the antireflective layer comprises titanium nitride;
removing the integrated circuit structure from the deposition chamber; and
titanium pasting the deposition chamber.

26. The method as recited in claim 22, prior to the step disposing the antireflective layer over the flash titanium layer, the steps further comprising:
if a wafer in the deposition chamber is not covered by a shield,
moving the shield so as to cover the wafer;
cleaning the target; and
moving the shield so as to uncover the wafer.

27. The method as recited in claim 26, wherein the target comprises titanium.

28. The method as recited in claim 27, wherein the step disposing the flash titanium layer over the interconnect conductor comprises sputtering the titanium target in the deposition chamber and wherein the step disposing the antireflective layer over the flash titanium layer comprises introducing nitrogen gas into the deposition chamber and sputtering the titanium target in the deposition chamber.
